(19) United States
(12) Patent Application Publication
(10) Pub. No.: US 2011/0089698 A1
(43) Pub. Date: Apr. 21, 2011

(54) Combination solar and dual generator wind turbine

(76) Inventor: William Ahmadi, Los Angeles, CA (US)

(21) Appl. No.: 12/460,778

(22) Filed: Jul. 24, 2009

(51) Int. Cl. F03D 9/00; H01L 31/042

(52) U.S. Cl. 290/55; 136/244

(57) ABSTRACT

A single or dual aligned synchronized generator and variable speed direct drive wind turbine for installation on a wind farm, solar and wind powered self watering farm, building, light post, atop roofs and other mountable locations employs either a vertical or horizontal shaft less wind turbine system. The system takes advantage of low or high wind speed conditions with specially designed geometrically shaped turbine blades of light weight. The hollow center allows the turbine to operate under less weight and stress than traditional turbine systems. The blades are designed to minimize negative forces, stresses and drag. Electrical energy may be stored or directly transmitted to a grid system. In addition the system employs a photovoltaic panel to collect solar energy to be used in addition to the wind energy created.

### CROSS REFERENCE TO RELATED APPLICATIONS

This application includes subject matter that is related to U.S. Provisional Patent Ser. No. 61/215,931 entitled “Dual Generator Wind Turbine”, and U.S. Provisional Patent No. 61/134,295 entitled “Combination wind and solar system” filed concurrently herewith, which is herein incorporated by reference.

### FIELD OF THE INVENTION

This invention relates to a single or dual aligned generator wind turbine and solar system.

### BACKGROUND

Wind energy has been harnessed for centuries and used for important purposes such as propelling ships, pumping water and grinding grain. More recently the use of the wind turbine coupled with generators has been used to produce electricity.

The use of wind energy is a viable substitute and alternative, and generally costly, however recent developments in the art point to a future of increased usage and lower costs overall.

The benefits of wind and solar energy cannot be underestimated. The earth has a finite supply of fossil fuels, thus developing new energy sources are critical for future growth and the wellbeing of mankind. In addition to offering an alternative to fossil fuels for energy, wind energy can also play an important role in reducing greenhouse gases, a major component of pollution and global warming.

For example, the use of pit mining brings with it inherent risks to mine workers health and CO2 emissions caused by burning coal.

Nuclear energy is currently favored as an alternative and clean energy, particularly in Europe where its use has increased over the decades. However its one large side effect acts as a deterrent to full favor, that is, the production and storage of nuclear wastes. Accordingly the U.S. Dept. of Energy estimates that the U.S. wind energy potential exceeds total U.S. energy consumption today. Thus wind is logically among the alternative energy sources that is receiving more attention today as a clean renewable source.

Prior art illustrates both vertical and horizontal axis turbines. Also illustrated is that horizontal-axis turbines are favored, and they are usually mounted on a tall tower, typically, with large blades. These larger blades in turn require a faster tip speed whereby a speed increase is needed between the turbine and generator. Conventional turbines are controlled to decrease their operating tip speed ratio in high winds. Lastly today's standard turbine blade is heavy, large and costly, three major reasons why the use of wind as an energy source remains minimal relative to its potential.

It is necessary thus to produce an improved wind turbine of a smaller more compact size which can produce an equal or even greater KWH to today's standard turbines. New configurations of the current wind turbines are indeed necessary to keep up with the ever increasing demand for wind energy.

As such, there have been many efforts to increase the efficiency of wind turbines before mass use is achieved. U.S. Pat. No. 7,484,363 Reidy, et al. discloses several embodiments to improve wind energy production capacity such as increased turbine speed and secondary turbines strategically placed between the primary turbines. This may result in a greater airflow across the turbines resulting in greater propeller speeds, however unless the actual design of the traditional blade is fundamentally improved, improvements mentioned above will only achieve minimal success at best.

Some have sought to increase wind production efficiency during irregular periods, such as when a fault occurs. A fault is a disturbance that results in the decrease in voltage output on the utility and transmission system for typically less than 500 milliseconds caused by short circuiting or improper grounding of at least one phase conductor. U.S. Pat. No. 7,432,686 Erdman et al. discloses a turbine which drives a pair of AC squirrel cage induction generators designed to produce electrical current during a fault condition. Inverter control is continued in a variable speed turbine system during a fault.

However these improvements do not fundamentally improve wind turbine performance as was previously noted, that is, greater performance during low wind peak times.

U.S. Pat. No. 7,425,776 Ketchum discloses a wind turbine consisting of multiple generators having a vertical post and vertical tubes whereby the generators are positioned vertically above each other. The turbines are cylindered in shape, the top being the smallest the bottom the largest. This design allows the smaller blades to rotate during low winds, thereby providing energy in such conditions. Yet such a device is large and requires heavy maintenance to support three individual rotating cylinders.

A wind turbine and generator that uses permanent magnet generators to produce energy is disclosed in U.S. Pat. No. 7,042,109 Gabry's wherein the wind turbine allows slow speed power generation and it is low in weight, and quiet in operation.

While this wind generation system boasts of multiple advantages, permanent magnetic generators do not include a field coil which would allow for the field coil voltage control.

When utilizing the NdFeB magnets, they suffer from significant cogging torque, which in turn can lock the rotor of the turbine in place and prevents the easy start of rotation.

### SUMMARY OF THE INVENTION

An object of the invention is to provide a dual aligned synchronized generator variable speed direct drive turbine topped by a photo-voltaic panel. Each generator may be composed of mini shafts whereby neither of the shafts run through the center of the turbine, which traditional turbines have. Instead, the shafts from the generators are connected to the ends of the central column of the turbine running through both generators. The turbine may also include a traditional central shaft. The turbines create mechanical energy whereby the generators convert said mechanical energy into an electrical energy source. A storage device is used to store the energy, such as a battery bank or the energy can be directly fed to a power grid. The system can also be chained connected, that is a row of wind turbines connected and synchronized where the energy is fed to transformers and then fed to a power grid. The shaft less center design of the turbine reduces the net weight of the turbine, as opposed to a full shafted turbine, thereby increasing the ease of revolution and increasing the RPM's possible by said turbine. The systems main embodiment employs a gearbox. Other embodiments may include a direct drive shaft without the need for a gearbox.

Each generator is enclosed behind and attached to circular sheeting on either side of each generator, whose circumference is equal to the outer lengths of the turbine blades. The outer sheeting composed of a wire grid or a semi-solid circular structure with air vents which allows cross winds to pass through without causing uplift wind forces to lift which may cause turbulence and or drag along the turbine blades. A larger circular fixed enclosure panel also secures the generator as well as the enclosure bars along the perimeter of the turbine unit. This double mounting stabilizes the generators to greatly reduce harmonic vibration, drag and shock of the generators and its blades.

The central column is primarily an open channel with a plurality of horizontal or vertical mini-blades, depending on whether the turbine is vertical or horizontal, around the entire circumference of the turbine. Said mini blades are attached to the interior bend of a turbine blade by means of rib bits along its side wall. The angled blade is a planar surface whereby it attaches to the neighboring blade at its inner tip. From atop this mini blade forms a star-shaped structure, where the individual blades are connected together by means of this plurality of mini blades running throughout the center of the turbine and possessing L-shaped plates to be ribbited to each individual blade. Thus the inner bent surface of the turbine blade is aligned with a ribbited vertical metallic surface wherein the open channels are aligned with the planar mini blades.

If the turbine is horizontal said blades are vertical, and act to redirect wind to the turbines themselves, a plurality of turbine blades are attached to the central column by means of rib bits.

The turbine blades are composed of a plurality of materials, preferably aluminum due to its light weight. The shape of the blades are a nearly ninety degree bend where the blade connection to the central column is angled with a right quarter bend of the blade edge, thus creating a more aerodynamic blade designed to operate under any wind direction. Along the corner edge of one blade leading to the tip edge of the very next turbine blade may be a wire, similar in size and scale to a bicycle spoke, to prevent warping, vibration or bending of said blades.

The turbine structure is enclosed behind a plurality of hollow enclosure bars running from one distal outer circular sheeting end to the other on the opposing end, and act to further stabilize the structure and also to prevent birds from entering the turbine members.

A solar panel is mounted atop the wind turbine structure for the purposes of gathering solar power.

A controller system utilizing either series charge controlling or shunt charge controlling may be coupled with other control circuitry and an inverter, and may be mounted together on the ground or along the unit in a non-assuming position.

Another object of the present invention is to provide a more consistent wind turbine unit that operates under low or high wind conditions. This object is achieved by means of the unique shape and weight of the present inventions turbine blades. The need for longer blades under heavier wind conditions is thus eliminated due to the more aerodynamic nature of the wind turbine, its lighter weight, and its design that allows for negative force winds to be reflected off of the blade surface in its leeward position minimizing the negative forces while eliminating problematic lift forces and drag caused by the wind.

Yet another object of the invention is to produce a greater more consistent flow of KWH. One of the greatest drawbacks to wind energy use happens to be the production of only intermittent energy, most systems face problems if the winds are too weak or too strong. A goal of the present invention is to gain greater tip speed with less blade speed energy necessary to provide a more constant flow of KWH, and more consistent sinusoidal waveforms.

Yet another object of the present invention is to provide a plurality of mountable places in which the unit may operate, such as, the side of a building, along a light post, in an energy farm, atop roofs, and even mountainous regions for example.

A second embodiment of the present invention is the use of the synchronized dual generator wind turbine system in combination with solar power to provide power both to a self watering farm system, with the remainder of energy produced provided to the electrical grid, or any chosen energy provider to provide energy to the city.

A third embodiment of the present dual synchronized generator wind turbine system is used in combination with solar power to provide power to a series of individual self watering planters, designed to be mountable in a plurality of places, with the remainder of the energy produced by said system to be sent to the electric grid for use by the city, or sent to a desirable location where excess power is needed.

Yet another embodiment of the present invention is to incorporate a standard central shaft between the dual generators, as is done in traditional wind turbine systems if desired, for example if the length and width of the turbine are greater than usual than a standard shaft may be used.

### DRAWINGS

### Brief Description of the Drawings

The following description should explain the present invention in detail on the basis of drawings. However, it is understood that the invention is not limited to the precise arrangements and instrumentalities shown.

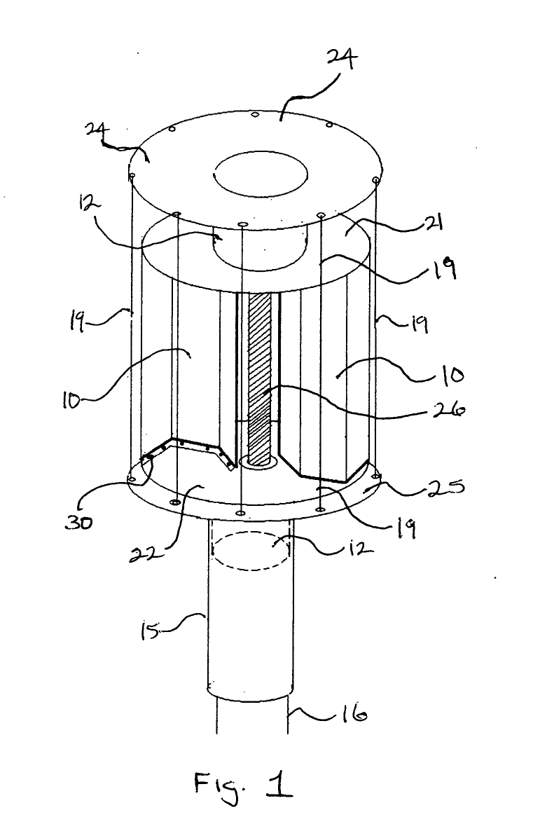

FIG. 1 is a three dimensional sectional view of a post mounted wind turbine with standard shaft.

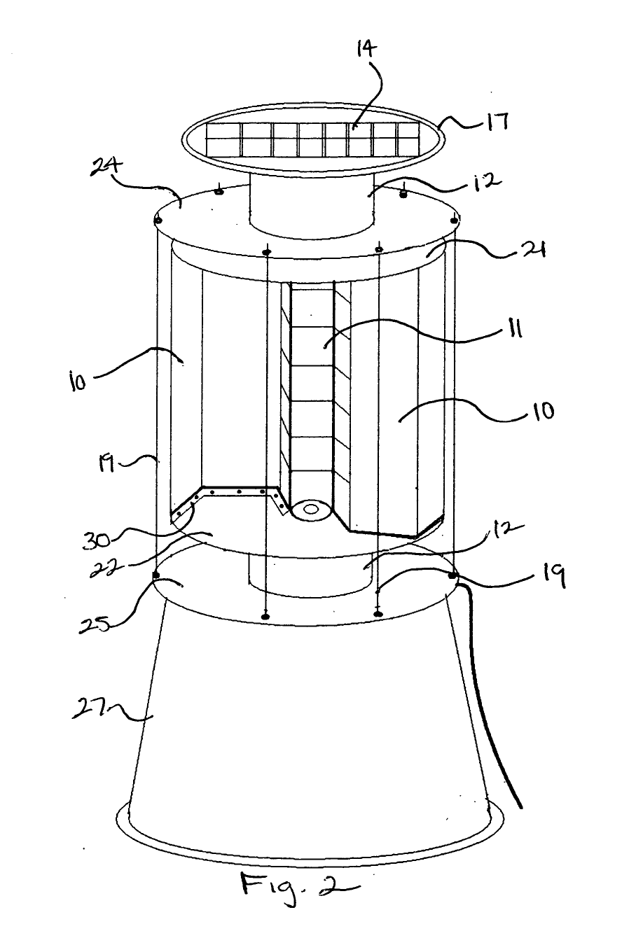

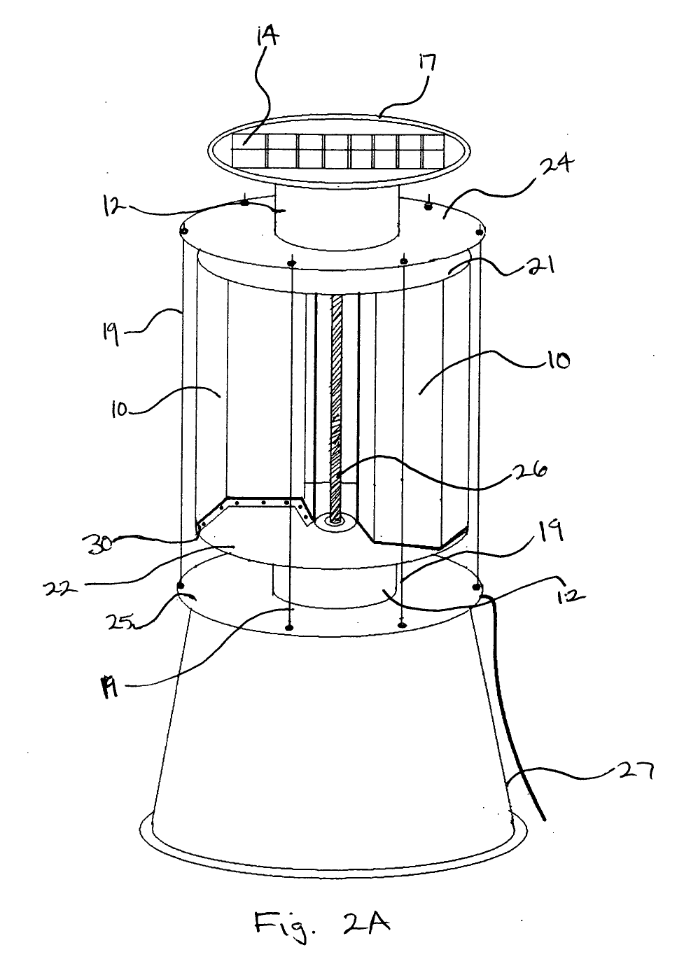

FIG. 2 is a two dimensional view of pyramid solar panel topped wind turbine with shaft less center.

FIG. 2A is a two dimensional view of a pyramid based solar panel topped wind turbine with standard shaft.

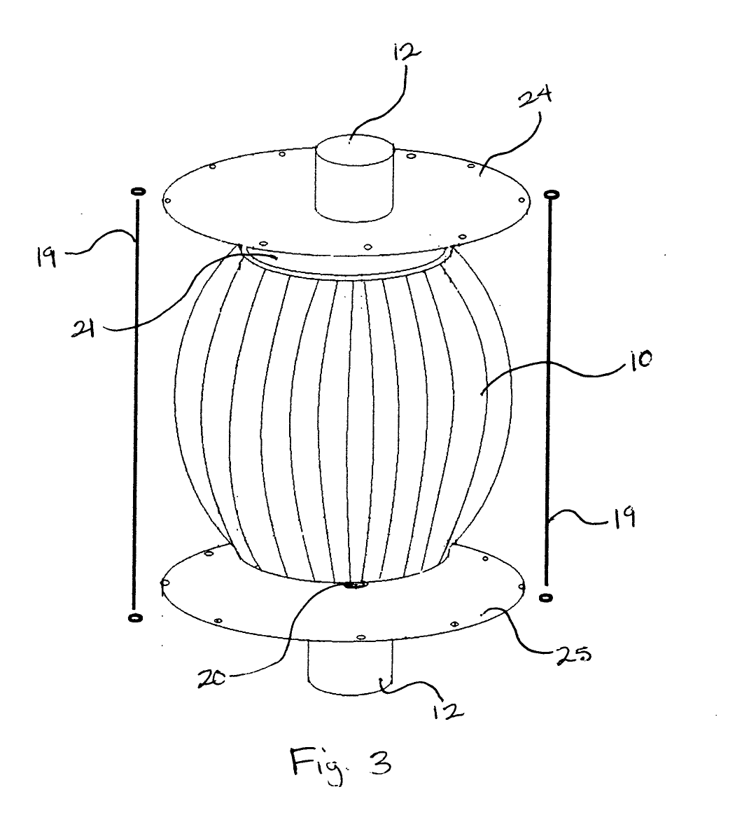

FIG. 3 is a three dimensional sectional view of eggbeater turbine

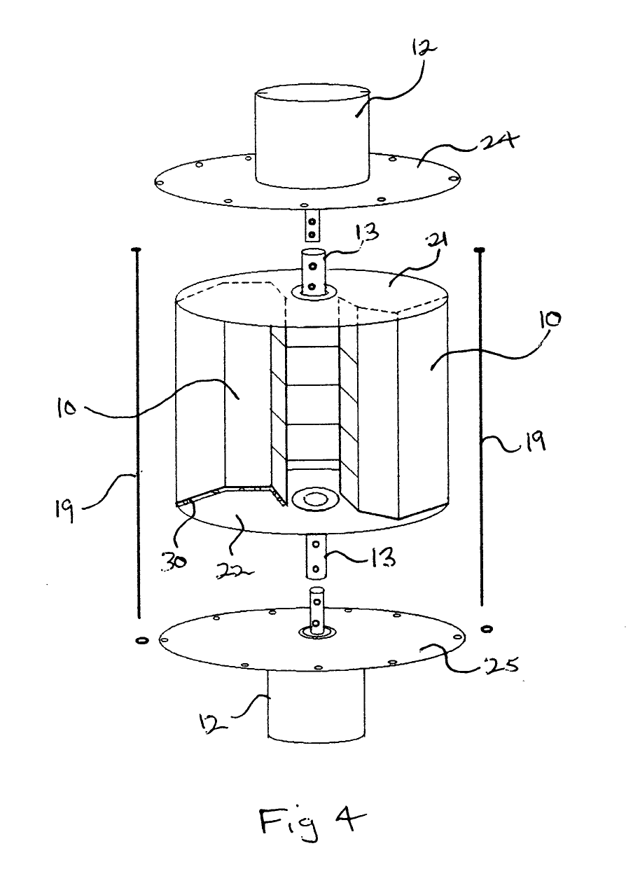

FIG. 4 is a three dimensional exploded view of the wind turbine with two mini shafts.

FIG. 4A is a three dimensional exploded view of the wind turbine with shaft.

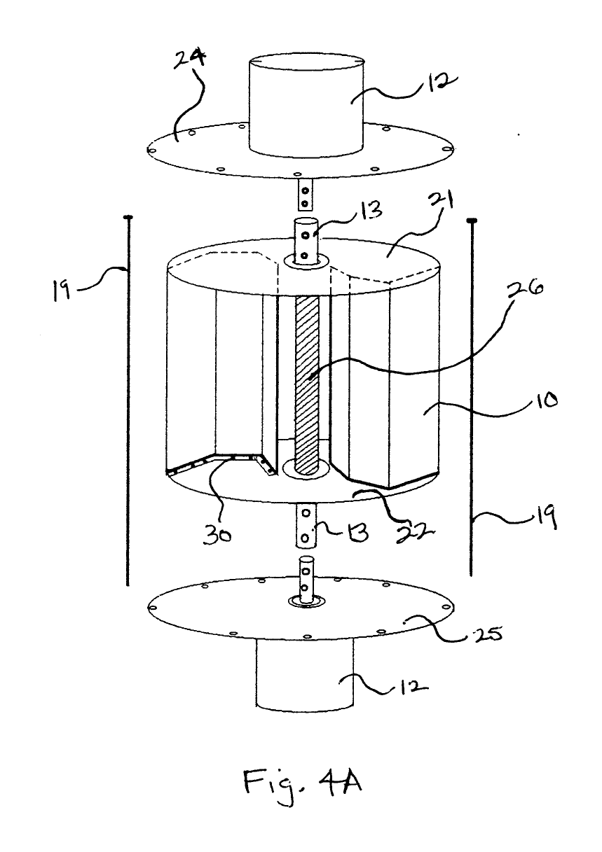

FIG. 5 is an arm post mounted side view of the wind turbine.

### DETAILED DESCRIPTION OF THE DRAWINGS

An embodiment of the present invention with a shaft is related in FIG. 1 where a three dimensional sectional view of the wind turbine with a standard shaft is provided. At the base of FIG. 1 attached to the lower body cap 25 is an enclosure for the generator 12 therein. A topside enclosure for a second generator 12 is attached to the upper body cap 24 at the opposing end. The wind turbine is secured to a post which may be of a plurality of sizes, said post consisting of both a male post 16 and female post 15 with an end secured to base generator 12 whereby said generator 12 slides up into the its mounting base matching the circumference of the and secured by nuts and bolts therein. The other end attached to the lower post by treaded nuts and bolts as well. Said lower body cap 25, and upper body cap 24 is circular in dimension and is equal in circumference to that of the surrounding enclosure bars 19 about the surface of the wind turbine. The upper body cap 24 along with the lower body cap 25 are composed of a screen mesh to allow possible turbulent air flow to escape the area of the turbine to aid in cooling the internal members of said turbine. A bearing 20 is found about the entering shaft to both the top and base generators 12.

Further along the shaft on both ends is a lower circular plate 22 at the base end of the turbine blades 10 and the upper circular plate 21 at the topside end of the wind turbine blades 10. The respective body caps both contain and stabilize said wind turbine blades 10 secured by rib bits along the upper circular plate 21 and lower circular plate 22 to 90 degree flange 30 and rib bitted along the upper circular plate 21 and the lower circular plate 22. Said upper and lower circular plates 21 & 22 are smaller in circumference than said upper and lower body caps 24 & 25, and revolve along with said turbine blade 10 whereas said upper and lower body caps 24 & 25 remain static along with said enclosure bars 19.

Spaced about the periphery of said wind turbine blades 10 are a plurality of evenly spaced enclosure bars 19 the outer circumference of the upper 24 and lower . Electrical wiring can be ran through the enclosure bars 19 which are internally insulated, from the control box wherein said electrical wiring runs from said enclosure bar 19 through the L-brace poles where a connection is made through the control box. The present embodiment consists of a standard through shaft 26 wherein said turbine blades 10 are attached. Said shaft 26 runs vertically throughout the turbines body centrally placed about through both upper and lower placed generators 12. Said upper plate 21 and lower plate 22 are composed of a metallic substance, preferably aluminum with a thickness of roughly ¼ of an inch or thicker respectively.

It is noted that said generators 12 are synchronized in revolutions per second as well as energy output with each other to maintain a fluid flow of electrical energy to the battery bank or a grid system. Said generators are set to produce identical current and phase while producing a steady sinusoidal waveform.

FIG. 2 is a three dimensional sectional view of the shaft-less center wind turbine. This embodiment of the present invention presents a water storage reservoir 27 for irrigating plants in a collapsible rack and row planter, on rooftops etc., as the wind turbine produces energy to either power a pump system or to send electrical energy to a grid. Said reservoir 27 is mounted at the base of the unit secured by a plurality of nuts and bolts. An infill opening allows for the refilling of the reservoir tank. A pair of generators 12 are placed at either ends of the turbine unit, one at the base of the turbine unit sits atop said reservoir 27 secured by screws or nuts and bolts, while the second generator 12 rests atop the wind turbine unit attached to the upper body cap 24. The generators 12 each possess mini shafts whereby the center of the wind turbine 10 is shaft-less, instead of a shaft a central structure of miniature support blades 11 are attached to the turbine blades 10 by means of a vertical frame structure wherein said miniature support blades 11 are attached by rib bits. This allows the wind turbine a partially open center whereby wind that may otherwise cause stresses and perhaps affect the pitch rotation of the blades, is allowed to freely flow through the central mini blades 11 via the space created between them. Structural support is provided by two outer circular plates, the upper body cap 24 and the lower body cap 25 which themselves are anchored to a plurality of enclosure bars 19 that surround the turbine unit and the reservoir 27. Said enclosure bars 19 act as a secondary means of structure support along the full perimeter of the unit whereas said upper body cap 24 and lower body cap 25 also provide structural support for both generators 12. A mini shaft enters the upper circular plate 21 and the lower circular plate 22 and is connected to said turbine blades 10 distal ends on the upper and lower ends of the turbine at the center of said turbine along the miniature support blades 11, attached by rib bits to the upper circular plate 21 on the upper end and the lower circular plate 22 on the lower end.

FIG. 2A is a pyramid based wind turbine topped by a solar panel as found in FIG. 2 however FIG. 2A consists of a shaft-less center which is composed of miniature support blades 11.

FIG. 3 illustrates an alternative embodiment of blade types that may be used. The turbine blade 10 here is sometimes called an eggbeater blade or a type of darrieus blade consisting of a semi oval shaped turbine which possesses a plurality of overlapping turbine blades 10 which are attached to the upper circular plate 21 and the lower circular plate 22 wherein a bearing 20 on each end of the turbine structure within the generator 12 is attached to the shaft 26. Said upper and lower plates 21 & 22 are attached to said turbine blades 10 by rib bits along a washer plate fitted on either ends of the turbine wherein said upper and lower plates 21 & 22 and washer act as a singular piece to reduce any vibrations that may occur otherwise. As before, the entire turbine structure is housed within the plurality of enclosure bars 19 attached to the upper body cap 24 and the lower body cap 25 which add structural integrity to the entire structure therein. It is clear from FIG. 5 that a plurality of different blade types may be used in the present invention, the choice of blade type may depend on the environmental conditions of the area where the turbine unit is to be employed. Said turbine blades 10 may also be fabricated in a way thereby allowing greater gaps between said blades 10 to increase internal air flow for the cooling of the generators 12.

FIG. 4 Is an exploded three dimensional view of the wind turbine that consists of a shaft less center whereby one mini shaft 26A is situated at the top of the upper circular plate 21 and a second mini shaft is situated below the base of the lower circular plate 22. Said mini shafts connect to the generator 12 shafts directly by bolts and nuts. Said generators 12 are located on the latitudinal top of the upper and lower body caps 24 & 25 wherein a centrally placed opening secures said generators 12 which consist of a stator and a rotor and a bearing from which said generator's 12 shaft emerges from. Situated along the outer perimeter of said upper body cap 24 and lower body cap 25 are fabricated openings whereby enclosure bars 19 are secured and act both to structurally secure said upper and lower body caps 24 & 25 to the wind turbine as well as act as a deterrent for birds and bats. Said enclosure bars 19 possess a hollowed center whereby electrical wiring to and from said generators 12 is routed to and from the electrical control system.

The shaft less center consists of a vertical columnar center, where the shaft is normally placed, and consists of horizontal metallic miniature support blades 11 which forms an attachment to the turbine blade 10 thereby allowing turbulent air to pass through the wind turbine open areas between said vertical bars of said miniature support blades 11 thereby decreasing turbulent air flow.

In this way said miniature support blades 11 act to increase the structural integrity of the actual wind turbine blades 10. In addition the blade is fabricated wherein its edge forms a 90 degree blade flange 30 with a planar surface that is rib bitted to both the upper circular plate 21 and the lower circular plate 22 at both distal ends of the turbine blade 10. Thus increasing the structural integrity of the turbine blades 10 along with said miniature support blades 11 to guard against warping and vibration of said turbine blades 10 therein.

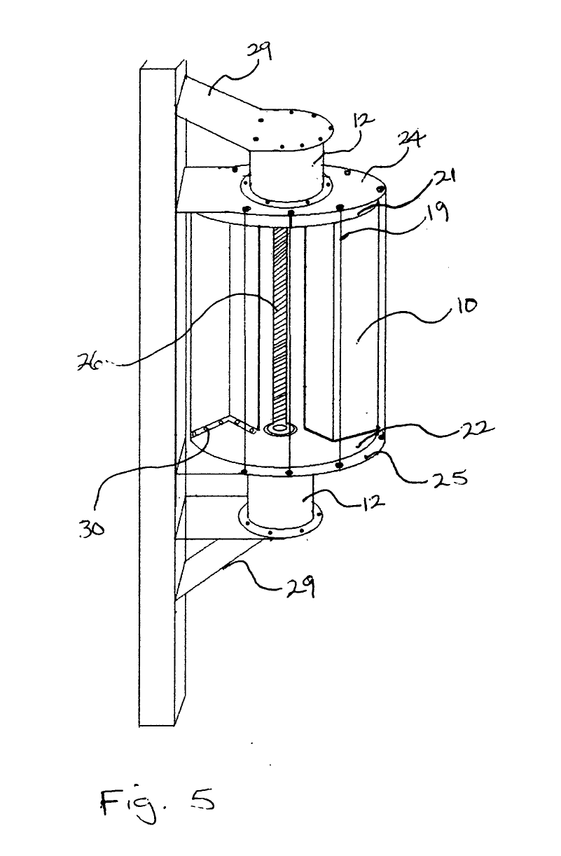

FIG. 4A is an exploded three dimensional view of FIG. 6 however with a traditional shaft along the center column of said wind turbine that leads to the upper and lower generators 12.

FIG. 5 is a post mounted wind turbine where a solar panel may or may not be mounted unto the top portion of the post mounting bracket 29 which is secured to a post in a vertical position with nuts and bolts and or screws attaching said wind turbine supported by the post mounting bracket 29 to the post itself along the upper latitudinal top and base. The post mounting bracket 29 along its circular distal end is secured to both top and base generators 12. The upper body cap 24 is modified in this embodiment as it forms a planar surfaced square shape to act as a base for the post mounted bracket 29 attached to the post and forms a circular upper body cap 24. The lower body cap 25 shaped in the fashion mentioned above, acts as a secondary support that attaches the turbine to the post. beneath the lower body cap 25 is the base generator 12 mounted to a second post mounting bracket which in turn is mounted to the post thereof. Said post mounting The unit consists of a plurality of enclosure bars 19 add structural integrity to the wind turbine. In this embodiment the wind turbine possesses a full shaft 26 which leads through openings in the upper circular plate 21 and the lower circular plate 22, each opening thereof consisting of at least one bearing 20. A plurality of turbine blades 10 may be composed from a plurality of materials and are secured to the upper circular plate 21 and the lower circular plate 22 by means of a 90 degree blade flange 30 attached by a plurality of rib bits. Said upper and lower circular plates 21 & 22 revolve along with the shaft 26 and turbine blades 10. The upper and lower body caps 24 & 25 remain static along with said enclosure bars 19.

All figures mentioned above are designed to allow for the easy mounting of a solar PV panel, the wattage thereof may be specified according to the specific needs and uses desired.

### LIST OF DRAWING REFERENCES

10. Turbine blade
11. Miniature support blade
12. Generator
13. Mini shaft
14. Solar panel
15. Female solar post
16. Male solar post
17. Solar pane frame
18. Solar adjuster
19. Enclosure bar
20. Bearing
21. Upper circular plate
22. Lower circular plate
23. Wire support bars
24. Upper body cap
25. Lower body cap
26. Shaft
27. Reservoir
28. Infill opening
29. Battery container

### CONCLUSION, RAMIFICATIONS, AND SCOPE

While there are shown and described herein certain specific alternative forms of the invention, it will be readily apparent to those skilled in the art that the invention is not limited, but is susceptible to various modifications and rearrangements in design and materials without departing from the spirit and scope of the invention. In particular, it should be noted that the present invention is subject to modification with regard to the dimensional relationships set forth herein and modifications in assembly, materials, size, shape and use.

I claim:

1. A combination wind turbine and solar system whereby two generators are aligned along the turbine whereby a;
wind turbine is a variable speed turbine;
wind turbine consists of at least one blade;
wind turbine is composed of a shaft less center;
wind turbine blades form a plurality of shapes and sizes;
wind turbine tip blade ends and corner edges are affixed with a metallic wire;
wind turbine is supported by horizontal or vertical top and bottom body caps;
wind turbine is enclosed by a top and bottom;
shaft less center housing;
each generator is mounted to an inner circular plate;
each generator is mounted to an outer circular plate;
the units components are mounted outside of wind turbine unit;
enclosure bars surround wind turbine unit;
a solar panel may be mounted atop said wind turbine unit to supply solar energy;
and, wind turbine may be mounted in or on a plurality of differing structures.

2. A combination wind turbine-and solar system according to claim 1, wherein said wind turbine consists of two or more blades.

3. A combination wind turbine and solar system according to claim 1, wherein said wind turbine is composed of a plurality of materials, preferably aluminum.

4. A combination wind turbine and solar system according to claim 1, wherein said wind turbine blade forms a near trapezoidal dimension of two or more near right angular bends forming a unique cup.

5. A combination wind turbine and solar system according to claim 1, wherein said wind turbine blade forms a savonius blade with airfoil.

6. A combination wind turbine and solar system according to claim 5, wherein said wind turbine blade forms a darrieus blade.

7. A combination wind turbine and solar system according to claim 5, wherein said wind turbine blade forms a C or S-shape blade.

8. A combination wind turbine and solar system according to claim 5, wherein said wind turbine blade is formed of a plurality of semi C-shaped blades, narrowly spaced apart similar to those blades of a rooftop ventilator.

9. A combination wind turbine and solar system according to claim 1, wherein said wind turbine upper and lower body caps act as a structural support to said wind turbine, are circular in shape, larger in circumference, and lie above and below said upper and lower circular plate whereby it is attached to said enclosure bars.

10. A combination wind turbine and solar system according to claim 9, wherein said wind turbine upper and lower plates are affixed to said turbine blades by means of a plurality of rib bits, screws or welds.

11. A combination wind turbine and solar system according to claim 1, wherein said wind turbine blade may be affixed to a metallic guy wire extending from the blade tip to the neighboring blade mid-section to reduce blade tip vibration and the warping of the blade.

12. A combination wind turbine and solar system according to claim 1, wherein said dual generators are mounted to the upper and lower body caps at either end of said generator by means of screws or nuts and bolts along generator housing.

13. A combination wind turbine and solar system according to claim, 1 wherein said outer circular body caps may be composed of wire mesh or a screen, or may be composed of a solid metallic substance.

14. A combination wind turbine and solar system according to claim 13, wherein said outer circular body caps are composed of a circular metallic inner disk, larger in circumference than said upper and lower inner plates and consisting of a circular opening about its middle for generator mounting, wherein a plurality of openings are arranged along the outer perimeter of said body caps whereby enclosure bars pass through and are attached and secured to said upper and lower body caps.

15. A combination wind turbine and solar system according to claim 1, wherein said upper and lower plates contain an opening about its center whereby said generators' mini shaft passes through and connects to said turbine. The area of said upper and lower plates revolves with said turbine inside of said enclosure bars.

16. A combination wind turbine and solar system according to claim 1, wherein said generators are mounted along the inner and outer surface of the upper and lower body caps and the by means of screws, and or nuts and bolts to add structural integrity to said turbine by limiting vibrations or movement along the generators axis, and by said generators stator, bearings and shaft.

17. A combination wind turbine and solar system according to claim 16, wherein said generators are synchronized.

18. A combination wind turbine and solar system according to claim 1, wherein said unit components such as, but not limited to a charge controller, and an inverter whose preferred embodiment is of a true sine wave type, are housed outside of the wind turbine unit thereof.

19. A combination wind and solar system according to claim 1, wherein said enclosure bars are attached to the distal ends of said upper and lower body caps and increase the structural integrity of said wind turbine.

20. A combination wind and solar system according to claim 19, wherein said enclosure bars possess a hollowed interior allowing for the passage therein of wiring to and from said generators. The distal ends of the enclosure bar are threaded about the exterior whereby bolts lock it into place.

21. A combination wind and solar system according to claim 19, wherein said enclosure bars surround and enclose said wind turbine thereby acting as a deterrent to prevent birds from reaching said turbine blades.

22. A combination wind and solar system according to claim 1, wherein said shaft-less center of the turbine is affixed to said turbine blades by rib bits and may be posted vertically and/or horizontally about the center of the surfaces of the upper and lower plates to which it is also affixed.

23. A combination wind and solar system according to claim 1, wherein said center of the wind turbine is composed of a regular through shaft, when desired, a generator affixed to each distal end, said turbine blades either affixed to both upper and lower plates and shaft or simply directly attached to said upper and lower plates.

24. A combination wind and solar system according to claim 22, wherein said shaft-less center is composed of a plurality of miniature metallic blades set horizontally in a vertical mounted wind turbine. Said blades are planar shaped whereby the L-bends along the ends are rib bitted along the bend of the accompanying blade to the inner edge of the following blade, thus interconnecting all turbine blades therein.

25. A combination wind and solar system according to claim 24, wherein said shaft-less center miniature support blades are placed along the four voids which create openings about the center of said wind turbine thereby acting as a center post connecting said turbine blades to increase structural integrity.

26. A combination wind and solar system according to claim 25, wherein said shaft-less center is formed of a semi-circular shape whereby said miniature support blades are also semi-circular in shape.

27. A combination wind and solar system according to claim 26, wherein said shaft-less center is formed of a square or rectangular shape, whereby said miniature support blades consists of a planar shape and are attached along all four sides of said shaft-less center.

28. A combination wind and solar system according to claim 1, wherein said solar panel is attached to a vertical column consisting of a bracket upon the upper generator housing to collect solar energy.

29. A combination wind and solar system according to claim 28, wherein said solar panel is adjustable to face the sun for as long as possible.

30. A combination wind and solar system according to claim 28, wherein said solar panel is contained within a metallic frame covered atop by glass, whereby a U-shaped member directly below is attached to said solar panel and generator housing thereby allowing for the eastern facing angle of said solar panel.

31. A combination wind and solar system according to claim 1, wherein said wind turbine may be mounted atop a light post, a building roof, along the side of a building or within a wind farm.

32. A combination wind and solar system according to claim 1, wherein said generator mini-shaft consists of a male portion extending from said generator and a female lower portion that extends from the central mini-shaft and are rib bitted or bolted together.

33. A combination wind and solar system according to claim 1, wherein said solar panel may or may not be included in said wind turbine unit.
